(19) United States
(12) Patent Application Publication
(10) Pub. No.: US 2011/0062578 A1
(43) Pub. Date: Mar. 17, 2011

(54) SEMICONDUCTOR DEVICE AND METHOD OF MANUFACTURING THE SAME

(75) Inventors: Fumimasa KATAGIRI, Tempe, AZ (US); Teruaki Chino, Nagano (JP); Akihiko Tateiwa, Nagano (JP)

(73) Assignee: SHINKO ELECTRIC INDUSTRIES CO., LTD., Nagano-shi (JP)

(21) Appl. No.: 12/856,934

(22) Filed: Aug. 16, 2010

(30) Foreign Application Priority Data
Sep. 14, 2009 (JP) 2009-211414

(51) Int. Cl. H01L 23/34; H01L 21/50

(52) U.S. Cl. 257/712; 438/122; 257/E23.08; 257/E21.499

(57) ABSTRACT

A semiconductor device includes a semiconductor chip having a connection electrode on a surface side, and a resin substrate sealing a periphery of the semiconductor chip and formed to have a thickness from a back surface of the semiconductor chip to a lower side thereof, and the resin substrate whose lower surface is positioned to a lower side than the back surface of the semiconductor chip. A wiring layer is connected directly to the connection electrode of the semiconductor chip without the intervention of solder.

### CROSS-REFERENCE TO RELATED APPLICATIONS

This application is based on and claims priority of Japanese Patent Application No. 2009-211414 filed on Sep. 14, 2009, the entire contents of which are incorporated herein by reference.

### BACKGROUND OF THE INVENTION

1. Field of the Invention

The present invention relates to a semiconductor device and a method of manufacturing the same, more particularly, a semiconductor device that is applicable in a packaging structure in which a periphery of a semiconductor chip is sealed with a resin substrate and wiring layers are connected to connection electrodes of the semiconductor chip and a method of manufacturing the same.

2. Description of the Related Art

In the prior art, there is the semiconductor device having such a structure that the periphery of the semiconductor chip is sealed with the resin substrate and the wiring layers are connected to the connection electrodes of the semiconductor chip. In such semiconductor device, the wiring layers can be connected directly to the connection electrodes of the semiconductor chip. Therefore, the solder bumps used to flip-chip mount the semiconductor chip can be omitted, and thus the chip can be made thin. Accordingly, wiring routes in the semiconductor device can be made shorter, and thus the inductances can be reduced. As a result, the structure that is effective in improving the power supply characteristics can be provided.

The technology similar to such semiconductor device is disclosed in Patent Literature 1 (WO 02/15266 A2), Patent Literature 2 (WO 02/33751 A2), and Non-Patent Literature 1 (Bumpless Build Up Layer Packaging (Intel Corporation Steven N. Towle et al.)).

As explained in the column of the related art described later, in the semiconductor device in the related art, the periphery of the semiconductor chip is sealed with the resin substrate, and then the build-up wirings which are connected to the connection electrodes of the semiconductor chip are formed.

The semiconductor chip and the resin have a different coefficient of thermal expansion each other. As a result, such a problem exists that a warp of the resin substrate easily occurs due to a thermal stress generated at a time of heat treatment applied when either the semiconductor chip is sealed with the resin or the build-up wirings are formed.

### SUMMARY OF THE INVENTION

It is an object of the present invention to provide a semiconductor device capable of preventing an occurrence of warp of a resin substrate located in the periphery of a semiconductor chip, in a semiconductor device having such a structure that the periphery of the semiconductor chip is sealed with the resin substrate, and a method of manufacturing the same.

The present invention is concerned with a semiconductor device, which includes a semiconductor chip having a connection electrode on a surface side; and a resin substrate sealing a periphery of the semiconductor chip and formed to have a thickness from a back surface of the semiconductor chip to a lower side thereof, and the resin substrate whose lower surface is positioned to a lower side than the back surface of the semiconductor chip.

In a preferred mode of the present invention, the resin substrate is formed to cover a part in the back surface of the semiconductor chip, and the opening portion of the resin substrate is arranged on the back surface of the semiconductor chip. Accordingly, the anchor portion of the resin substrate is provided on the back surface of the semiconductor chip. Therefore, even when a thermal stress occurs due to a difference in a coefficient of thermal expansion between the semiconductor chip and the resin substrate, an occurrence of warp of the resin substrate can be prevented.

Otherwise, the resin substrata may be arranged to the outside containing the edge part in the back surface of the semiconductor chip, and the opening portion of the resin substrate may be arranged on the whole of the back surface of the semiconductor chip. Also, the whole of back surface of the semiconductor chip may be covered with the resin substrate. In the case of these modes, an occurrence of warp of the resin substrate can be prevented similarly.

Then, the wiring layers which are connected directly to the connection electrodes without the intervention of solder are formed on the semiconductor chip and the resin substrate.

Also, in another preferred mode of the present invention, the heat sink which is connected to the back surface of the semiconductor chip and is made of copper, or the like may be provided in the opening portion of the resin substrate.

In this mode, in the case that the semiconductor chip whose amount of heat generation is large is employed, the sufficient radiating property can be obtained, and also an occurrence of warp of the resin substrate can be prevented.

As explained above, in the present invention, an occurrence of warp of the resin substrate located in the periphery of the semiconductor chip can be prevented, and the semiconductor device with high reliability can be constructed.

### BRIEF DESCRIPTION OF THE DRAWINGS

FIGS. 1A to 1C are sectional views (#1) showing a method of manufacturing a semiconductor device in the related art which is associated with the present invention;

FIGS. 2A to 2C are sectional views (#2) showing the method of manufacturing the semiconductor device in the related art which is associated with the present invention;

FIG. 3 is views (#1) showing a method of manufacturing a semiconductor device according to a first embodiment of the present invention;

FIG. 4 is views (#2) showing the method of manufacturing the semiconductor device according to the first embodiment of the present invention;

FIGS. 5A to 5C are sectional views (#3) showing the method of manufacturing the semiconductor device according to the first embodiment of the present invention;

FIGS. 6A to 6C are sectional views (#4) showing the method of manufacturing the semiconductor device according to the first embodiment of the present invention;

FIGS. 7A and 7B are sectional views explaining such a mode that a semiconductor chip in which connection electrodes are protruded is employed, in the method of manufacturing the semiconductor device according to the first embodiment of the present invention;

FIG. 8 is a sectional view showing a semiconductor device according to a first variation of the first embodiment of the present invention;

FIG. 9 is a sectional view showing a semiconductor device according to a second variation of the first embodiment of the present invention;

FIG. 10 is a sectional view showing a semiconductor device according to a third variation of the first embodiment of the present invention;

FIG. 11 is views (#1) showing a method of manufacturing a semiconductor device according to a second embodiment of the present invention;

FIG. 12 is views (#2) showing the method of manufacturing the semiconductor device according to the second embodiment of the present invention;

FIGS. 13A to 13C are sectional views (#3) showing the method of manufacturing the semiconductor device according to the second embodiment of the present invention;

FIG. 14 is a reduced plan view of the semiconductor device in FIG. 13C of the present invention when viewed from the lower side;

FIG. 15 is a sectional view showing a semiconductor device according to a variation of the second embodiment of the present invention; and

FIGS. 16A to 16C are reduced plan views of the semiconductor device in FIG. 15 when viewed from the lower side, which show an example of a shape of divided opening portions of the resin substrate respectively.

### DETAILED DESCRIPTION OF THE PREFERRED EMBODIMENTS

Embodiments of the present invention will be explained with reference to the accompanying drawings hereinafter.

### Related Art

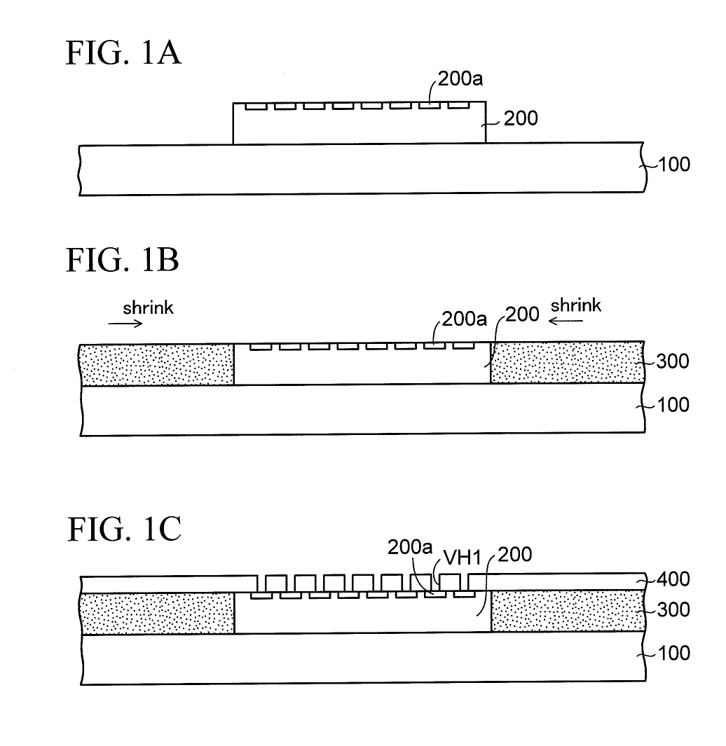

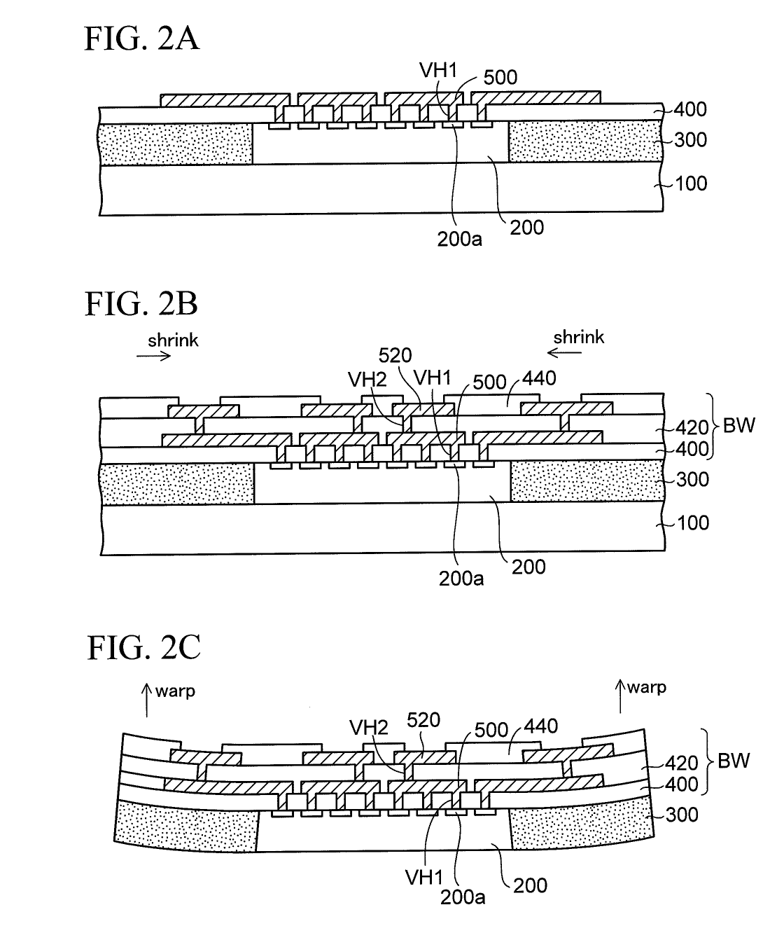

Prior to the explanation of embodiments of the present invention, the problem in the related art which is associated with the present invention will be explained hereunder. FIGS. 1A to 1C and FIGS. 2A to 2C are sectional views showing a method of manufacturing a semiconductor device in the related art.

In the method of manufacturing the semiconductor device in the related art, as shown in FIG. 1A, first, a semiconductor chip 200 is arranged on a supporting member 100. The semiconductor chip 200 is arranged on the supporting member 100 in a state that its connection electrodes 200a are directed upward.

Actually, a large number of semiconductor chips 200 are arranged side by side on the supporting member 100. But one semiconductor chip 200 is shown on the supporting member 100 in FIG. 1A.

Then, as shown in FIG. 1B, powder resins (not shown) are put on the supporting member 100 and the semiconductor chip 200, and the resin is cured by heating the resin while pressurizing the resin by the die (not shown). Accordingly, a periphery of the semiconductor chip 200 is sealed with a resin substrate 300. At this time, such a state is obtained that the connection electrodes 200a of the semiconductor chip 200 are exposed.

In this case, a coefficient of thermal expansion (CTE) of the resin is larger than a coefficient of thermal expansion of the semiconductor chip 200 (silicon). Therefore, the resin shrinks toward the semiconductor chip 200 side due to a thermal stress caused at a time when the resin is cured by heating and then is cooled to a room temperature. Accordingly, the resin substrate 300 located in the periphery of the semiconductor chip 200 is easy to warp upward.

In the case that the rigidity of the supporting member 100 is high, no warp occurs apparently at a point of this time. However, a warp occurs due to a residual stress after the supporting member 100 is removed from the resin substrate 300 and then the resin substrate 300 is cut. Also, in the case that the rigidity of the supporting member 100 is low, in some cases the supporting member 100 warps to follow a warping stress of the resin substrate 300.

Then, as shown in FIG. 1C, a semi-cured resin film is pasted onto the resin substrate 300, and then a first interlayer insulating layer 400 is formed by curing the semi-cured resin film with heating. Then, first via holes VH1 each reaching the connection electrode 200a of the semiconductor chip 200 are formed by processing the first interlayer insulating layer 400 by the laser.

Then, as shown in FIG. 2A, first wiring layers 500 each connected to the connection electrodes 200a of the semiconductor chip 200 via the first via holes VH1 (via conductors) are formed.

Then, as shown in FIG. 2B, a second interlayer insulating layer 420 for covering the first wiring layers 500 is formed similarly, and then second via holes VH2 each reaches a connection part of the first wiring layer 500 are formed in the second interlayer insulating layer 420.

Then, second wiring layers 520 each connected to the first wiring layer 500 via the second via hole VH2 (via conductor) are formed on the second interlayer insulating layer 420. Then, a solder resist 440 in which opening portions are provided on connection parts of the second wiring layers 520 is formed.

Accordingly, a two layered build-up wiring BW connected to the connection electrodes 200a of the semiconductor chip 200 is formed.

Also in forming the build-up wiring BW, a thermal stress is caused by the heating process in step of forming the first and second interlayer insulating layers 400, 420, or the like. Therefore, the first and second interlayer insulating layers 400, 420 shrink toward the semiconductor chip 200 side, and thus the resin substrate 300 is further easy to warp.

Then, as shown in FIG. 2C, the supporting member 100 is removed from the semiconductor chip 200 and the resin substrate 300, and then the resin substrate 300 and the build-up wiring BW are cut together. Thereby, individual semiconductor devices are obtained.

At this time, in the case that the rigidity of the supporting member 100 is high, a residual stress in the resin substrate 300 and the build-up wiring BW is released as the warp of the resin substrate 300. Thus, it is in a state where the resin substrate 300 located in the periphery of the semiconductor chip 200 warps upward. When the warp of the resin substrate 300 is caused, it is difficult to mount the semiconductor device on the mounting substrate with good reliability.

As described above, the semiconductor device in the related art has the problem that the warp is easy to occur in the resin substrate 300. As a result of an inventor's earnest study, the inventor of this application found that an occurrence of warp can be reduced by forming the resin substrate to have a thickness from the back surface of the semiconductor chip to the lower side.

### First Embodiment

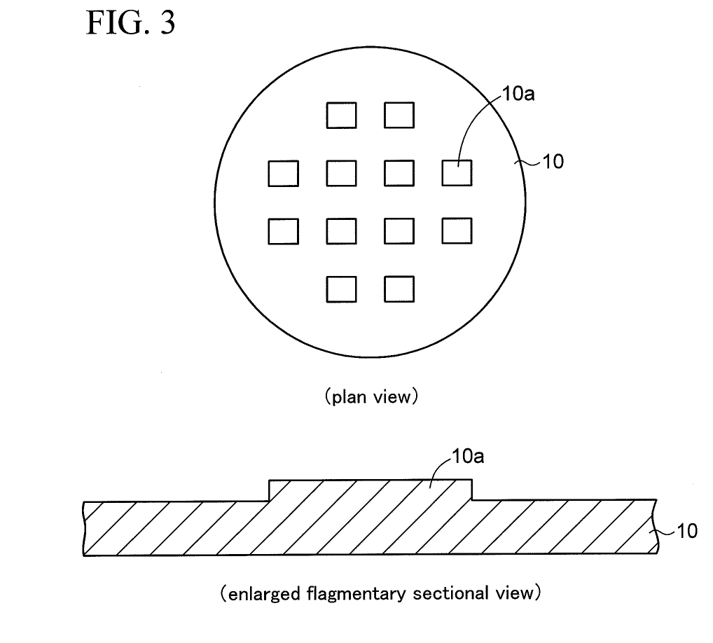

FIG. 3 to FIG. 6 are views showing a method of manufacturing a semiconductor device according to a first embodiment of the present invention. The semiconductor device of the present invention is also called a semiconductor package.

In the method of manufacturing the semiconductor device according to the first embodiment, as shown in FIG. 3, first, a copper substrate 10 (metal substrate) is prepared as a supporting member, and then a resist (not shown) is patterned by the photolithography. Then, the copper substrate 10 is wet-etched until a halfway position of the thickness direction while using the resist as a mask.

Accordingly, convex portions 10a each protruding upward are formed on the surface side of the copper substrate 10. As shown in a plan view of FIG. 3, a plurality of convex portions 10a are formed side by side to the copper substrate 10. Other metal substrates made of aluminum, and the like may be employed in place of the copper substrate 10. Also, preferably the convex portions 10a of the copper substrate 10 should be formed like a rectangular shape when viewed like a plane.

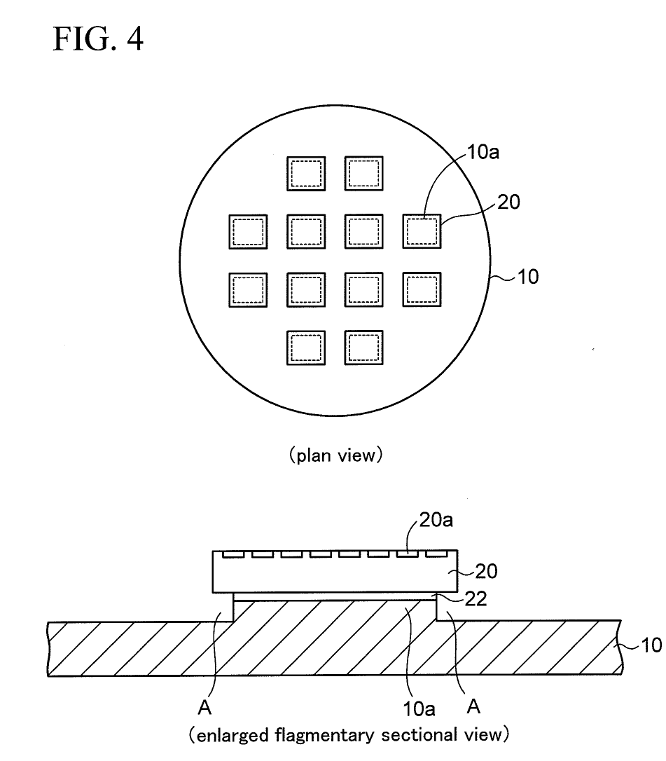

Then, as shown in FIG. 4, a semiconductor chip 20 (LSI chip) on the surface side of which connection electrodes 20a are exposed is prepared. The semiconductor chip 20 is obtained by cutting a silicon wafer (not shown) in which circuit elements such as transistors, or the like and a multilayer wiring for connecting these elements are provided in a chip area respectively. The connection electrodes 20a of the semiconductor chip 20 are connected to the multilayer wiring.

As the semiconductor chip 20, for example, a logic LSI such as CPU, or the like, is employed.

Then, the semiconductor chip 20 is fixed on each convex portion 10a of the copper substrate 10 by an adhering resin 22 respectively. The semiconductor chip 20 is arranged such that the connection electrodes 20a are directed upward. In the case that it is necessary to radiate the heat generated from the semiconductor chip 20, the adhering resin 22 having a high thermal conductivity is employed.

The convex portion 10a of the copper substrate 10 is provided so as to form a resin substrate which has a thickness (that is, the resin substrate protrudes) from the back surface of the semiconductor chip 20 to the lower side. In the example in FIG. 4, an area of the semiconductor chip 20 is set larger than an area of the convex portion 10a of the copper substrate 10 such that an edge part of the back surface of the semiconductor chip is covered with the resin substrate. Then, the semiconductor chip 20 is arranged on the convex portion 10a such that a visor portion A is provided like a ring under the edge part of the back surface of the semiconductor chip 20.

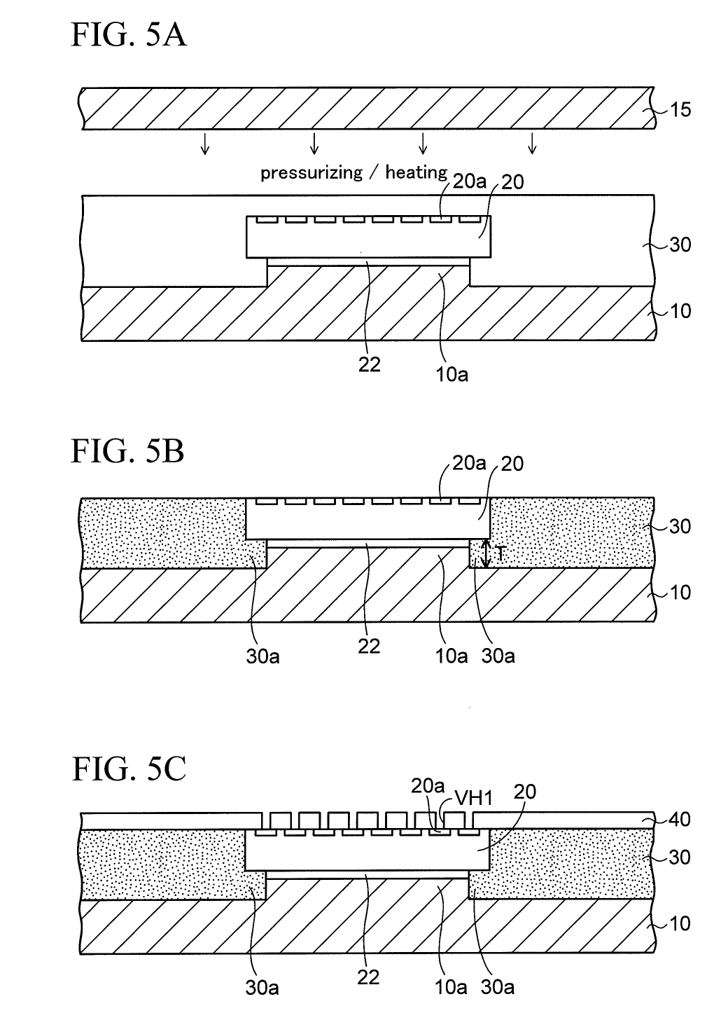

In the case that the convex portions 10a of the copper substrate 10 is formed with a rectangular shape when viewed like a plane, this convex portions 10a has a similar shape to a planar shape (rectangular shape) of the semiconductor chip 20. Accordingly, when the convex portions 10a should be formed with a rectangular shape which is smaller than the planar shape of the semiconductor chip 20, an anchor portion 30a having a predetermined width (see FIG. 5B described later) can be formed uniformly on the edge part of the back surface of the semiconductor chip 20, thus above mode is preferable.

Here, the shape of the convex portions 10a of the copper substrate 10 may be set to various shapes such as a circular shape, a polygonal shape, etc. when viewed like a plane.

Also, the convex portion 10a on which one semiconductor chip 20 is arranged may be divided into a plurality of convex portions, and the convex portion 10a may be constructed from an aggregate of a plurality of divided convex portions.

Otherwise, in the case that the back surface of the semiconductor chip 20 is not covered with the resin substrate, an area of the convex portion 10a of the copper substrate 10 is set equally to an area of the semiconductor chip 20, and such a situation is set that the side surfaces of the semiconductor chip 20 and the side surfaces of the convex portion 10a of the copper substrate constitute an identical surface.

That is, in the present embodiment, the area of the semiconductor chip 20 is set equal to or larger than the area of the convex portion 10a of the copper substrate 10.

Then, as shown in FIG. 5A, powder resins such epoxy resins, or the like are put on the copper substrate 10 and the semiconductor chip 20. Then, the resins are pressed downward by a die 15 while heating the resins in a temperature atmosphere of 150 to 170° C. Accordingly, as shown in FIG. 5B, the powder resins are melted and cured and concurrently the resin is molded by the die 15. Thus, a resin substrate 30 is formed from the upper side of the copper substrate 10 to the periphery (surrounding area) of the semiconductor chip 20.

At this time, such a situation is obtained that the connection electrodes 20a of the semiconductor chip 20 are exposed. In the case that the resin still remains on the connection electrodes 20a of the semiconductor chip 20, surfaces of the connection electrodes 20a can be exposed with good reliability by executing the polishing such as CMP, or the like.

As described above, the semiconductor chip 20 is arranged on the convex portion 10a of the copper substrate 10 such that the visor portion A is provided under the edge part of the back surface of the semiconductor chip 20. Accordingly, the resin substrate 30 which seals the semiconductor chip 20 is formed to have a thickness T under the back surface of the semiconductor chip 20 and to have the ring-like anchor portion 30a which covers the edge part of the back surface of the semiconductor chip 20. That is, the lower surface of the resin substrate 30 is formed to be positioned at lower side than the back surface of the semiconductor chip 20.

The resin substrate 30 is formed in the periphery of the semiconductor chip 20 with such structure, thereby even when a coefficient of thermal expansion is different between the semiconductor chip 20 and the resin substrate 30, the occurring thermal stress can be dispersed. Therefore, an occurrence of warp of the resin substrate 30 can be prevented.

In this way, the resin substrate 30 is formed such that the surface side of the semiconductor chip 20 is exposed from the resin substrate 30 and the periphery of the side of the semiconductor chip 20 is sealed with the resin substrate 30.

Then, as shown in FIG. 5C, a semi-cured resin film made of epoxy, polyimide, or the like is pasted on the semiconductor chip 20 and the resin substrate 30, and the resin film is cured by the heat treatment, thereby a first interlayer insulating layer 40 is formed. Then, first via holes VH1 each reaching the connection electrode 20a of the semiconductor chip 20 are formed by processing the first interlayer insulating layer 40 by the laser, or the like.

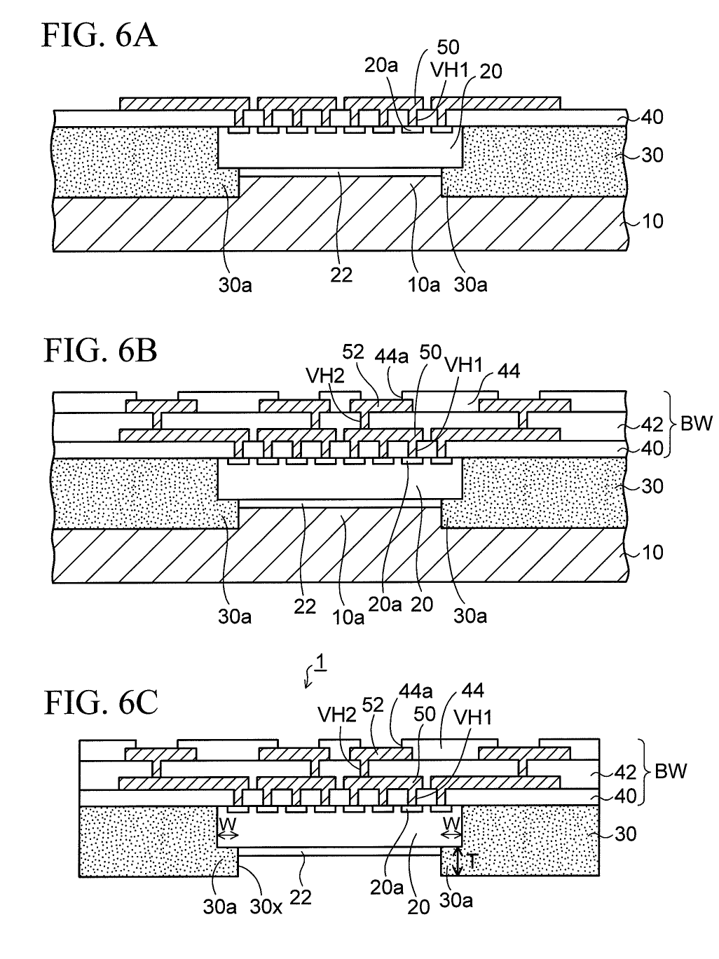

Then, as shown in FIG. 6A, first wiring layers each connected to the connection electrodes 20a of the semiconductor chip 20 via the first via holes VH1 (via conductors) are formed.

In the present embodiment, the semiconductor chip 20 is not connected to the wiring substrate by using the flip-chip mounting, but the first wiring layers 50 are connected directly to the connection electrodes 20a of the semiconductor chip 20. Therefore, there is no need to employ the bump electrodes such as the solder bumps, or the like, which are used for the flip-chip mounting and whose height is high (e.g., 50 to 100 μm). As a result, the semiconductor chip of the thinner type can be achieved.

The first wiring layers 50 can be formed by various wiring forming methods. The method of forming the first wiring layers by using the semi-additive process will be explained by way of example. First, a seed layer (not shown) made of copper, or the like is formed in the first via holes VH1 and on the first interlayer insulating layer 40 by the sputter method or the electroless plating. Then, a plating resist (not shown) in which opening portions are provided in the portions where the first wiring layers 50 are arranged is formed.

Then, a metal plating layer (not shown) made of copper, or the like is formed in the first via holes VH1 and the opening portions of the plating resist by the electroplating utilizing the seed layer as the plating power feeding path. Then, the plating resist is removed, and the first wiring layers 50 are obtained by etching the seed layer while using the metal plating layer as a mask.

Then, as shown in FIG. 6B, a second interlayer insulating layer 42 for covering the first wiring layers 50 is formed by the similar method, and then second via holes VH2 each reaching the first wiring layer 50 are formed in the second interlayer insulating layer 42. Then, second wiring layers 52 each connected to the first wiring layer 50 via the second via hole VH2 (via conductor) are formed on the second interlayer insulating layer 42 by the similar method.

Then, a solder resist 44 in which opening portions 44a are provided on connection parts of the second wiring layers 52 is formed. Then, as the need arises, a contact layer (not shown) is formed on the connection parts of the second wiring layers by forming nickel/gold plating layers in order from the bottom, or the like.

Accordingly, a two-layered build-up wiring BW is formed on the semiconductor chip 20 and the resin substrate 30. The first and second wiring layers 50, 52 of the build-up wiring BW are formed to extend on the first and second interlayer insulating layers 40, 42 located over the surface of the resin substrate 30 respectively.

Then, as shown in FIG. 6C, by removing the copper substrate 10 by means of the wet etching, the adhering resin 22 formed on the back surfaces of the semiconductor chip 20 is exposed. The copper substrate 10 can be removed selectively with respect to the resin substrate 30 and the semiconductor chip (the adhering resin 22).

Then, as also shown in FIG. 6C, the resin substrate 30 and the build-up wiring BW on the boundary parts between the respective semiconductor chips 20 are cut. Thus, individual semiconductor devices 1 are obtained.

As shown in FIG. 6C, in the semiconductor device 1 of the first embodiment, the periphery of the side of the semiconductor chip 20 having the connection electrodes 20a on the surface side is sealed with the resin substrate 30. The surface side of the semiconductor chip 20 is exposed from the resin substrate 30. That is, the surface side of the semiconductor chip 20 is not covered with the resin substrate 30. And the upper surface of the semiconductor chip 20 and the upper surface of the resin substrate 30 are formed to constitute an identical surface substantially. The resin substrate 30 acts as the supporting substrate which supports the semiconductor chip 20.

The resin substrate 30 which seals the periphery of the semiconductor chip 20 is formed from the surface position of the periphery of four sides of the semiconductor chip 20 to the back surface side, and also is formed to have a thickness T from the back surface of the semiconductor chip 20 to the lower side. A thickness T of the resin substrate 30 can be set arbitrarily, but preferably such thickness T should be set to 1 to 200 μm.

Also, the resin substrate 30 has the ring-like anchor portion 30a which covers the edge part of the back surface of the semiconductor chip 20. The anchor portion 30a extends from the edge part of the back surface of the semiconductor chip 20 to the inside by width W. A width W of the anchor portion 30a is set to 50 to 150 μm.

Accordingly, an opening portion 30x of the resin substrate 30 is arranged on the center portion of the back surface of the semiconductor chip 20. Also, the adhering resin 22 having a high thermal conductivity is formed on the back surface of the semiconductor chip 20 in the opening portion 30x of the resin substrate 30.

In this manner, the resin substrate 30 is caused to protrude downward from the back surface of the semiconductor chip 20 by a thickness T, thereby a structure that capable of preventing a warp of the resin substrate 30 can be obtained.

The build-up wiring BW (the first and second wiring layers 50, 52, the first and second interlayer insulating layers 40, 42, the solder resist 44) obtained by the foregoing method is formed on the semiconductor chip 20 and the resin substrate 30. The first wiring layers 50 are connected directly to the connection electrodes 20a of the semiconductor chip 20. The number of stacked layers of the build-up wiring BW can be set arbitrarily.

In the semiconductor device 1 of the present embodiment, unlike the case where the semiconductor chip is flip-chip mounted via the solder bumps, the connection electrodes 20a of the semiconductor chip 20 are connected directly to the first wiring layers 50. Accordingly, the wiring routes in the semiconductor device 1 can be shortened by the thinner type, and thus the inductance can be reduced. Therefore, a structure that is effective in improving the power supply characteristics can be obtained.

Also, a pitch of the connection electrodes 20a of the semiconductor chip 20 is converted into a desired wider pitch by the first and second wiring layers 50, 52. Therefore, the first and second wiring layers 50, 52 are also called the re-wiring.

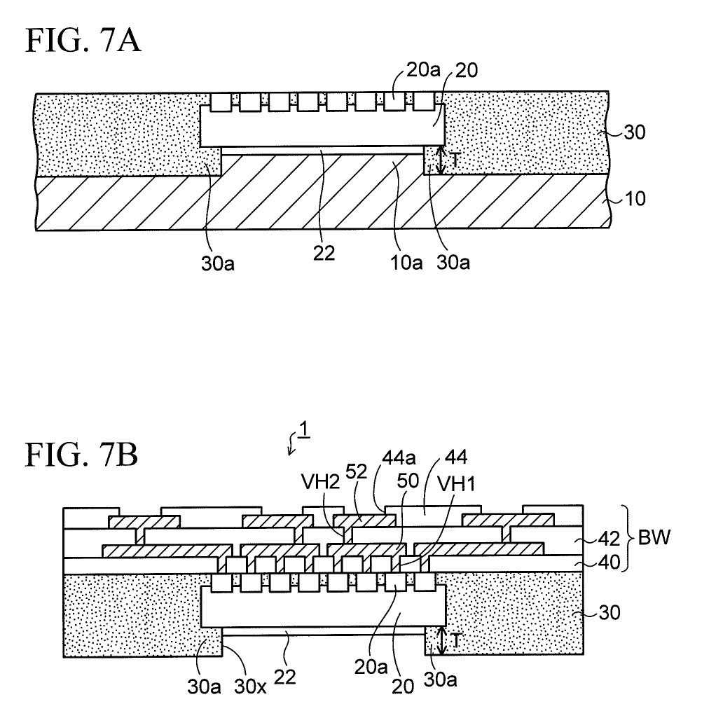

Here, as shown in FIG. 7A, the connection electrodes 20a of the semiconductor chip 20 may be formed to protrude upward. In this case, a resin of the resin substrate 30 is also formed in areas between the connection electrodes 20a on the semiconductor chip 20 by carrying out the similar steps as those in FIG. 4 to FIG. 5B mentioned above.

At this time, the semiconductor chip 20 having the connection electrodes 20a which protrude like a column respectively is employed. The connection electrodes 20a are made of metal such as copper, or the like, and a projection height is set to about 30 μm.

Then, as shown in FIG. 7B, the build-up wiring BW connected to the connection electrodes 20a is formed in a state that a resin of the resin substrate 30 is filled in the areas between the connection electrodes 20a on the semiconductor chip by carrying out the similar steps as those in FIG. 5C to FIG. 6C. In FIG. 7B, remaining elements are similar to those in FIG. 6C.

In the case of this mode, the element surface of the semiconductor chip 20 is also sealed with a resin of the resin substrate 30. Therefore, the semiconductor chip 20 can be protected more preferably.

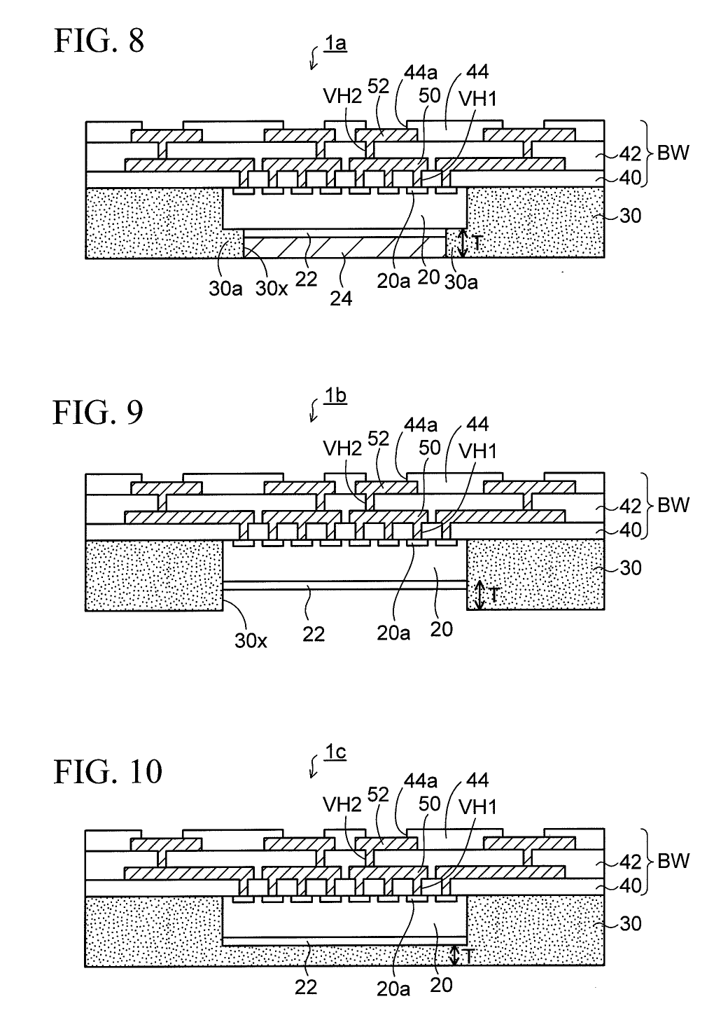

In FIG. 8, a semiconductor device 1a according to a first variation of the first embodiment is shown. Like the semiconductor device 1a of the first variation, in the semiconductor device 1 in FIG. 6C, the convex portion 10a of the copper substrate 10 may be left in the opening portion 30x of the resin substrate 30, and may be utilized as a heat sink 24 which is connected to the semiconductor chip 20.

In this case, in the above steps in FIGS. 6B and 6C, the major portions of the copper substrate 10 in the thickness direction are removed from the back surface side by the wet etching, and then the remaining copper substrate 10 is polished by the CMP, or the like until the lower surface of the resin substrate 30 is exposed.

Accordingly, the heat sink 24 made of copper can be left in the opening portion 30x of the resin substrate 30 with good precision. In FIG. 8, the heat sink 24 is formed of copper whose thermal conductivity is high. In this event, the heat sink 24 may be formed on the basis of forming the convex portion to a metal substrate having a radiating property, such as aluminum, or like, in place of the copper substrate 10.

In the semiconductor device 1a according to the first variation, even when the semiconductor chip 20 whose amount of heat generation is large is employed, a heat from the semiconductor chip 20 can be released easily from the heat sink 24 to the outside. Therefore, reliability of the semiconductor device can be ensured.

Also, in the above example of the semiconductor device 1 in FIG. 6C, a covering rate ((area of a covering portion of the resin substrate 30/area of the back surface of the semiconductor chip 20)×100) of the resin substrate 30 on the back surface of the semiconductor chip 20 is adjusted in a range of more than 0% but below 100%. Like a semiconductor device 1b according to a second variation of the first embodiment in FIG. 9, the back surface side of the semiconductor chip 20 may be exposed wholly by setting a covering rate of the resin substrate 30 to 0%. In this case, the resin substrate 30 is formed to have a thickness T downward in the outer area containing the edge part in the back surface of the semiconductor chip 20.

Otherwise, like a semiconductor device 1c according to a third variation of the first embodiment in FIG. 10, the back surface side of the semiconductor chip 20 may be covered wholly with the resin substrate 30 which has a thickness T under the adhering resin 22 by setting a covering rate of the resin substrate 30 to 100%. In this case, the copper substrate 10 may be removed completely from the structure in FIG. 6B, and then either a resin sheet may be pasted in the opening portion 30x from which the back surface side of the semiconductor chip 20 is exposed, or a liquid resin may be coated.

In this manner, in the present embodiment, the resin substrate 30 may be formed to seal the periphery of the semiconductor chip 20 and also have a thickness T downward from any part in the back surface of the semiconductor chip 20, and the lower surface of the resin substrate 30 may be positioned at lower side than the back surface of the semiconductor chip 20.

Also, in the semiconductor devices 1, 1b in FIG. 6C, FIG. 7B, and FIG. 9, a heat spreader may be joined to the back surface of the semiconductor chip 20. Also, in the semiconductor device 1a in FIG. 8, a heat spreader may be joined further to the heat sink 24.

The inventor of this application focused on both a covering rate of the resin substrate 30 on the back surface of the semiconductor chip 20 and a thickness T of the resin substrate 30 from the back surface of the semiconductor chip 20, and investigated how an amount of warp of the semiconductor device is changed when the covering rate and the thickness are changed respectively.

In the data given in Table 1 and Table 2 hereunder, in the case that an amount of warp has a plus value, the edge part of the semiconductor device warps upward, and in the case that an amount of warp has a minus value, the edge part of the semiconductor device warps downward.

TABLE 1
amount of warp of semiconductor device in first embodiment

| | T = 50 μm | T = 100 μm | T = 150 μm | T = 200 μm |
|---|---|---|---|---|
| covering rate | amount of | amount of | amount of | amount of |
| (%) | warp (μm) | warp (μm) | warp (μm) | warp (μm) |
| 0 | 85 | 78 | 76 | 74 |
| 20 | 81 | 78 | 75 | 74 |
| 40 | 79 | 75 | 70 | 66 |
| 60 | 75 | 64 | 52 | 41 |
| 80 | 68 | 51 | 34 | 18 |
| 100 | 62 | 39 | 18 | 2 |

The results are given in Table 1. As shown in Table 1, a covering rate of the resin substrate 30 is allocated in the range of 0 to 100% and a thickness T of the resin substrate 30 is allocated in the range of 50 to 200 μm, and then an amount of warp of the semiconductor device was investigated under respective combined conditions.

As shown in Table 1, an amount of warp of the semiconductor device is suppressed to 100 μm or less under all conditions, and a warp of the semiconductor device can be reduced rather than the related art by causing the resin substrate 30 to protrude downward from the back surface of the semiconductor chip 20 by a thickness T. By suppressing a warp of the semiconductor device roughly to 100 μm or less, the semiconductor device can be mounted on the mounting substrate with good reliability.

According to the careful investigation on the results in Table 1, such a tendency is found that an amount of warp is reduced in all thicknesses T of the resin substrate 30 as a covering rate of the resin substrate 30 is increased. An amount of warp is reduced particularly when a covering rate of the resin substrate 30 is about 50% or more, and an amount of warp can be suppressed to a minute amount (about 50 μm or less) when a thickness T is 200

Also, from another viewpoint, an amount of warp can be suppressed to a minute amount (about 50 μm or less) under the conditions that a covering rate of the resin substrate 30 is 80% or more and a thickness T of the resin substrate 30 is in a range of 150 to 200 μm.

In the structure of the semiconductor device 1 in FIG. 6C, when a covering rate of the resin substrate 30 is large, an area of the anchor portion 30a of the resin substrate 30 is increased. Therefore, a stress that the resin substrate 30 warps toward the upper side of the semiconductor chip 20 can be suppressed, and thus an occurrence of warp can be prevented.

Here, in the above mode, the opening portion is arranged collectively in the resin substrate 30 on the back surface of the semiconductor chip 20. In this event, as explained in a second embodiment described later, the similar advantages can be also achieved by arranging to divide the opening portion of the resin substrate 30 on the back surface of the semiconductor chip 20.

### Second Embodiment

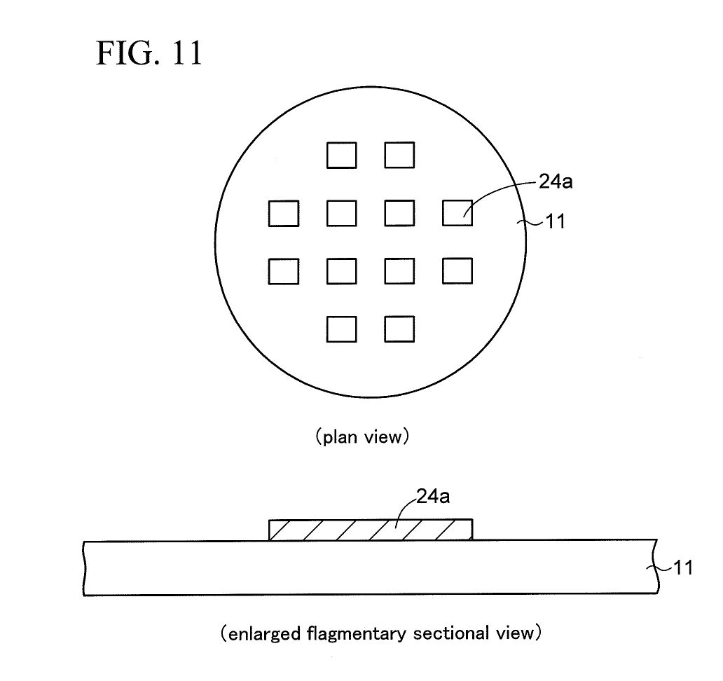

FIG. 11 to FIG. 13 are views showing a method of manufacturing a semiconductor device according to a second embodiment of the present invention. A feature of the second embodiment resides in that, in place of the convex portions formed by etching the copper substrate, the convex portions are formed by printing a copper paste on the supporting member. In the second embodiment, detailed explanation of the steps similar to those in the first embodiment will be omitted.

In the method of manufacturing the semiconductor device of the second embodiment, as shown in FIG. 11, first, convex portions 24a are formed by printing a copper paste (metal paste) on a supporting member 11. As shown in a plan view in FIG. 11, like the first embodiment, a plurality of convex portions 24a are formed side by side on the supporting member 11.

For example, the convex portion 24a is formed like a rectangular shape when viewed like a plane. Also, the convex portion 24a on which one semiconductor chip 20 is arranged may be divided into a plurality of convex portions, and the convex portion 24a is constructed from an aggregate of a plurality of divided convex portions.

The metal paste is such a material that metallic powders such as copper powders, or the like are contained in a resin such as an epoxy resin, a polyimide resin, or the like.

As described later, the supporting member 11 is removed selectively with respect to the convex portions 24a made of copper. Therefore, in the preferred example, the release agent is formed in a surface of the supporting member 11, and thus the supporting member 11 and the convex portions 24a can be separated easily.

Otherwise, as the material of the supporting member 11, the material that can be removed by the etching selectively to the convex portions 24a (copper) may be employed. As such material, a metal such as nickel, aluminum, or the like, for example, can be employed.

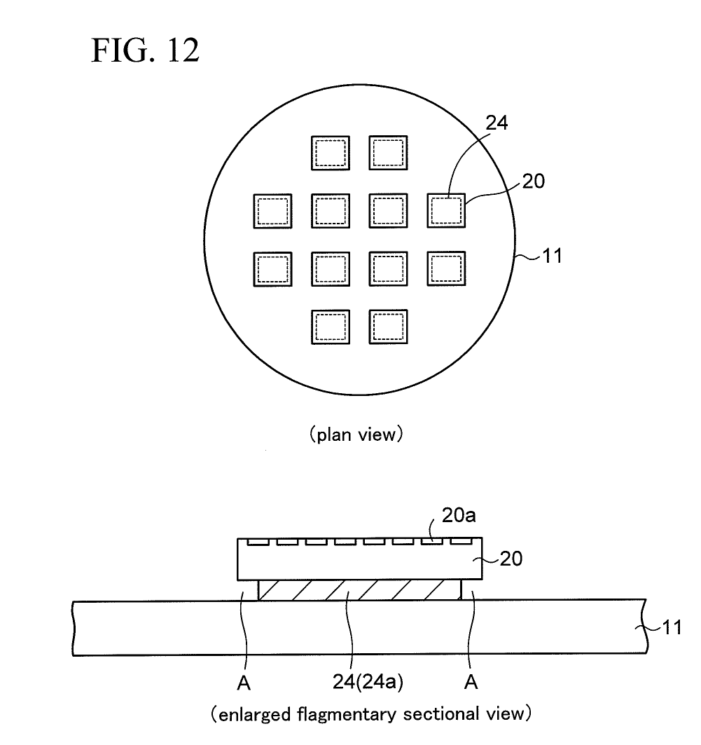

Then, as shown in FIG. 12, the semiconductor chip 20 is arranged on a plurality of convex portions 24a on the supporting member 11 respectively such that their connection electrodes 20a are directed upward. Then, the convex portions 24a (copper pastes) are heated at a temperature of about 150° C. and dried, and thus the back surfaces of the semiconductor chips 20 are adhered onto the convex portions 24a (copper portion) respectively. Accordingly, the heat sink 24 formed of the copper portion is formed on the back surfaces of the semiconductor chips 20 respectively.

At this time, like the first embodiment, the area of the semiconductor chip 20 is set equal to or larger than the area of the convex portion 24a, and the ring-like visor portion A is provided under the edge part of the back surface of the semiconductor chip 20.

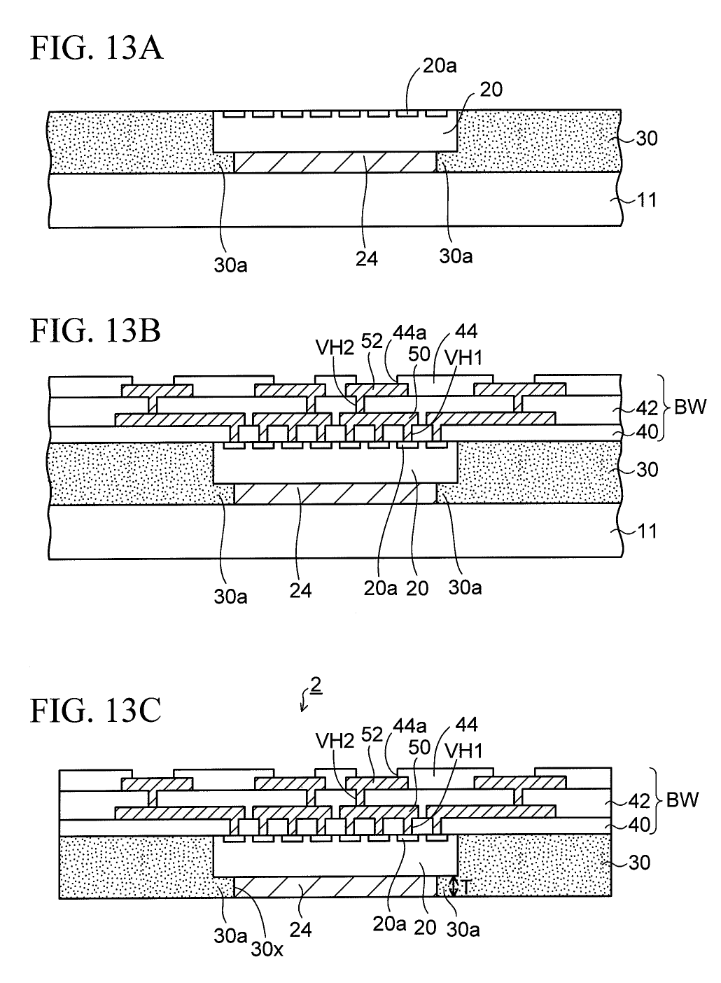

Then, as shown in FIG. 13A, a resin is formed from the upper side of the supporting member 11 to the periphery of the semiconductor chip 20 by the similar method in the first embodiment. Thus, the periphery of the semiconductor chip 20 is sealed with the resin substrate 30.

Then, as shown in FIG. 13B, the two-layered build-up wiring BW connected to the connection electrodes 20a of the semiconductor chip 20 is formed on the semiconductor chip 20 and the resin substrate 30 by the similar method in the first embodiment.

Then, as shown in FIG. 13C, the supporting member 11 is removed from the resin substrate 30 and the heat sink 24 on the back surface of the semiconductor chip 20. Then, the resin substrate 30 and the build-up wiring BW on the boundary parts of the respective semiconductor chips 20 are cut. Thus, a semiconductor device 2 of the second embodiment is obtained.

The semiconductor device 2 of the second embodiment has the substantially same structure as the semiconductor device 1a (FIG. 8) of the first variation of the first embodiment. That is, the resin substrate 30 which seals the semiconductor chip 20 is formed to have a thickness T downward from the back surface of the semiconductor chips 20, and the heat sink 24 made of copper is provided in the opening portion of the resin substrate 30. Since the heat sink 24 is provided on the back surface of the semiconductor chips 20, even when the semiconductor device whose amount of heat generation is large is employed, reliability of the semiconductor device can be ensured.

In this case, the heat sink 24 is formed of the copper paste whose thermal conductivity is high. But any metal paste containing other metallic powders having a radiating property, e.g., a silver paste, or the like, may be employed. Alternatively, the heat sink 24 may be formed of a resin having a high thermal conductivity.

Like the first embodiment, in the semiconductor device 2 in which the heat sink 24 is provided on the back surface in the second embodiment, the inventor of this application focused on a covering rate of the resin substrate 30 and a thickness T of the resin substrate 30 (25 to 150 μm in the second embodiment), and investigated how an amount of warp of the semiconductor device is changed when the covering rate and the thickness are changed respectively.

TABLE 2
amount of warp of semiconductor device in second embodiment

| | T = 25 μm | T = 50 μm | T = 100 μm | T = 150 μm |
|---|---|---|---|---|
| covering rate | amount of | amount of | amount of | amount of |
| (%) | warp (μm) | warp (μm) | warp (μm) | warp (μm) |
| 0 | −4 | −72 | −155 | −191 |
| 20 | 17 | −39 | −116 | −156 |
| 40 | 38 | −5 | −71 | −112 |
| 60 | 55 | 27 | −23 | −59 |
| 80 | 67 | 48 | 13 | −16 |
| 100 | 74 | 62 | 39 | 18 |

The results are given in Table 2. As shown in Table 2, when a thickness T of the resin substrate is set to 25 μm, an amount of warp can be suppressed to a minute amount (−4 μm (almost zero)) by setting a covering rate of the resin substrate 30 to 0% and providing the heat sink 24 on the whole of the back surface of the semiconductor chips 20. Also, when a thickness T of the resin substrate 30 is set to 50 μm, an amount of warp can be suppressed to a minute amount (−5 μm (almost zero)) at a covering rate of the resin substrate 30 of about 40%.

Also, when a thickness T of the resin substrate is set to 100 μm, there is such a tendency that an amount of warp is decreased as a covering rate of the resin substrate 30 is increased gradually (up to about 80%), and an amount of warp is decreased to the minimum (13 μm) at a covering rate of about 80%.

Also, when a thickness T of the resin substrate 30 is set to 150 μm, there is such a tendency that an amount of warp is decreased as a covering rate of the resin substrate 30 is increased gradually (up to about 80%), and an amount of warp is decreased to the minimum (−16 μm) at a covering rate of about 80%.

In this manner, the resin substrate 30 is formed in the periphery of the semiconductor chip 20 to have the thickness under the back surface of the semiconductor chips 20 and also the heat sink 24 is provided on the back surface of the semiconductor chips 20, thereby an occurrence of warp of the resin substrate can be reduced while ensuring the sufficient radiating property.

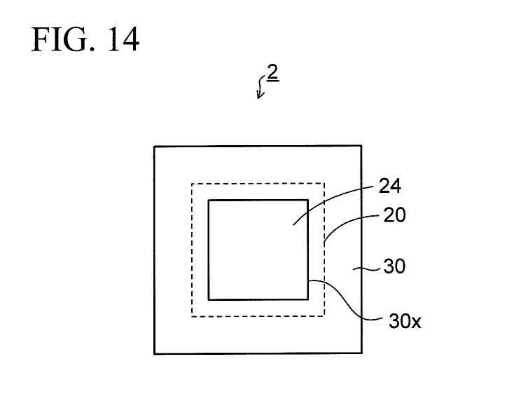

When the opening portion 30x in the resin substrate 30 on the back surface of the semiconductor chips 20 in FIG. 13C is viewed from the lower side of the semiconductor device 2, as shown in a fragmental plan view of FIG. 14, such opening portion 30x is opened collectively on the back surface of the semiconductor chips 20.

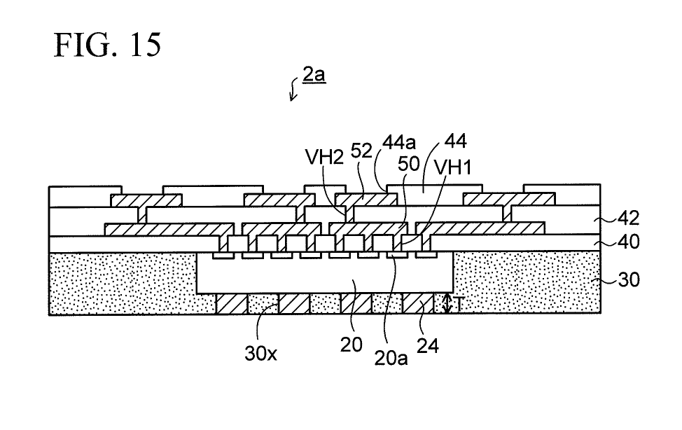

As the way of a semiconductor device 2a according to a variation of the second embodiment in FIG. 15, the opening portion 30x of the resin substrate 30 may be formed to be divided on the back surface of the semiconductor chip 20. In the case of this mode, in the above steps in FIG. 11, a copper paste is printed like island shapes on each chip arranging area, and then mutually separated convex portions (radiating portions) are formed. Then, in the above steps in FIG. 13A, a resin is filled through the spaces between the convex portions (radiating portions) arranged like the island shapes, and thus a resin of the resin substrate 30 is filled in the areas between respective heat sinks 24.

By arranging a large number of opening portions 30x of the resin substrate 30 to divide them on the back surface of the semiconductor chip 20, a thermal stress can be dispersed rather than the case where the opening portion 30x is provided collectively. Therefore, an occurrence of warp can be further reduced. Also, in the opening portion 30x of the resin substrate 30 located on the back surface of the semiconductor chip 20, to arranging to divide the opening portion 30x by more larger number is more better as effective of the prevention of the warp.

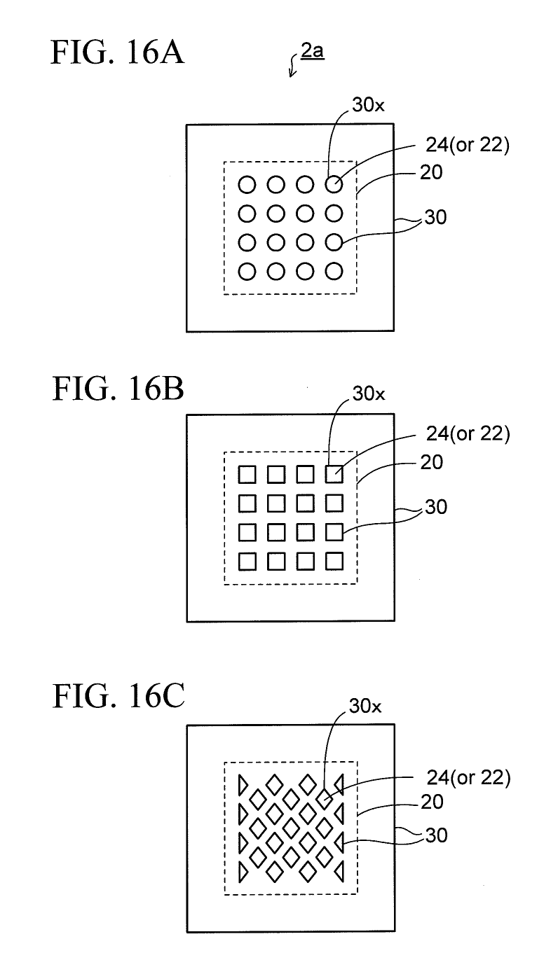

The opening portions 30x of the resin substrate 30 arranged on the back surface of the semiconductor chip 20 can be set to various shapes. As shown in FIG. 16A, a larger number of circular opening portions 30x are arranged in the resin substrate 30, and the heat sink 24 may be formed in the circular opening portions 30x respectively.

Also, as show in FIG. 16B, a larger number of quadrangular (square or rectangular) opening portions 30x may be arranged in the resin substrate 30, and the heat sink 24 may be formed in the quadrangular opening portions respectively. Otherwise, as shown in FIG. 16C, a larger number of rhombic opening portions 30x may be arranged in the resin substrate 30, and the heat sink 24 may be formed in the rhombic opening portions respectively.

In the foregoing first embodiment, the similar advantages can be achieved by dividing the opening portion 30x of the resin substrate 30. In this case, the pattern shapes of the resist formed on the copper substrate 10 are changes in the above steps in FIG. 3 in the first embodiment such that the convex portions 10a are formed to coincide with the opening portions 30x of the resin substrate 30 in FIG. 15. Then, the semiconductor chip 20 is mounted across a plurality of convex portions 10a, and then the resin substrate 30 is formed.

In this event, in the case that the opening portion 30x of the resin substrate 30 is divided in FIG. 6C of the foregoing first embodiment, in FIG. 16, the adhering resin 22 formed on the back surface of the semiconductor chip 20 is exposed from the opening portions 30x of the resin substrate 30.

What is claimed is:

1. A semiconductor device, comprising:
a semiconductor chip having a connection electrode on a surface side; and
a resin substrate sealing a periphery of the semiconductor chip and formed to have a thickness from a back surface of the semiconductor chip to a lower side thereof, and the resin substrate whose lower surface is positioned to a lower side than the back surface of the semiconductor chip.

2. A semiconductor device according to claim 1, further comprising:
a wiring layer formed on the surface side of the semiconductor chip and a upper surface side of the resin substrate, and connected to the connection electrode.

3. A semiconductor device according to claim 1, wherein the resin substrate is formed to cover a part in the back surface of the semiconductor chip, and an opening portion of the resin substrate is arranged on the back surface of the semiconductor chip.

4. A semiconductor device according to claim 3, wherein the opening portion of the resin substrate is arranged to be divided into a plurality of opening portions.

5. A semiconductor device according to claim 3, wherein a heat sink connected to the back surface of the semiconductor chip is provided in the opening portion of the resin substrate.

6. A semiconductor device according to claim 5, wherein the heat sink is formed of copper.

7. A semiconductor device according to claim 1, the surface side of the semiconductor chip is exposed from the resin substrate and the periphery of a side of the semiconductor chip is sealed with the resin substrate.

8. A method of manufacturing a semiconductor device, comprising the steps of:
preparing a supporting member on which a convex portion is provided;
arranging a semiconductor chip on the convex portion to direct a connection electrode of the semiconductor chip upward;
forming a resin substrate from an upper side of the supporting member to a periphery of the semiconductor chip in a state that the connection electrode is exposed; and
obtaining the resin substrate sealing the periphery of the semiconductor chip, and have a thickness from a back surface of the semiconductor chip to a lower side thereof, by removing the supporting member.

9. A method of manufacturing a semiconductor device according to claim 8, wherein, in the step of preparing the supporting member on which the convex portion is provided, the supporting member is formed by etching a metal substrate until a halfway position in a thickness direction to provide the convex portion, and
in the step of removing the supporting member, simultaneously the convex portion is removed to expose a back surface side of the semiconductor chip, or the convex portion is left and is utilized as a heat sink connected to the back surface of the semiconductor chip.

10. A method of manufacturing a semiconductor device according to claim 8, wherein, in the step of preparing the supporting member on which the convex portion is provided, the convex portion is provided by forming a metal paste on the supporting member, and
in the step of removing the supporting member, the convex portion is utilized as a heat sink connected to the back surface of the semiconductor chip, by removing the supporting member selectively to the convex portion.

11. A method of manufacturing a semiconductor device according to claim 8, after the step of forming the resin substrate, and before the step of removing the supporting member, further comprising the step of:
forming a wiring layer connected to the connection electrode on the semiconductor chip and the resin substrate.

12. A method of manufacturing a semiconductor device according to claim 8, wherein an area of the semiconductor chip is set equal to or larger than an area of the convex portion provided to the supporting member.
